(19) United States
(12) Patent Application Publication
(10) Pub. No.: US 2025/0188642 A1
(43) Pub. Date: Jun. 12, 2025

(54) METHOD OF FORMING A HIGH-TEMPERATURE SUPERCONDUCTING SINGLE CRYSTAL AND A HIGH-TEMPERATURE SUPERCONDUCTING SINGLE CRYSTAL FORMED THEREBY

(71) Applicants: HYUNDAI MOTOR COMPANY, Seoul (KR); KIA CORPORATION, Seoul (KR); SEOUL NATIONAL UNIVERSITY R&DB FOUNDATION, Seoul (KR)

(72) Inventors: Kyung Sik Choi, Seoul (KR); Hoo Dam Lee, Seoul (KR); Tae Gyu Lee, Seoul (KR); Hyung Kwan Jang, Uijeongbu-si (KR); Byung Ho Min, Suwon-si (KR); Jun Hyeok Choi, Suwon-si (KR); Kee Hoon Kim, Seoul (KR); Yeahan Sur, Suwon-si (KR); Jungwoo Lee, Seoul (KR); Sukho Kim, Hwaseong-si (KR); Chung Ha Park, Seoul (KR)

(73) Assignees: HYUNDAI MOTOR COMPANY, Seoul (KR); KIA CORPORATION, Seoul (KR); SEOUL NATIONAL UNIVERSITY R&DB FOUNDATION, Seoul (KR)

(21) Appl. No.: 18/734,576

(22) Filed: Jun. 5, 2024

(30) Foreign Application Priority Data
Dec. 12, 2023 (KR) 10-2023-0179978

(51) Int. Cl. C30B 11/14; C30B 11/00; C30B 29/22

(52) U.S. Cl. CPC C30B 11/14; C30B 11/003; C30B 29/225

(57) ABSTRACT

A method of forming a high-temperature superconducting single crystal is capable of facilitating a high-temperature superconducting single crystal containing rare-earth metals to grow using a multilayer seed. The method includes: preparing a rare earth barium copper oxide (ReBCO)-based precursor containing rare-earth metals; preparing a plurality of seeds that differ in lattice constant; placing the prepared seeds on top of the precursor through stacking; melting a portion of the precursor by heating the precursor to a peritectic temperature thereof or higher; and growing a single crystal by cooling the precursor to a crystal growth temperature thereof to match a crystal orientation of the seeds. Despite being used to increase the area and maintain the soundness of the single-crystalline specimen in most single-crystal growth, a buffer herein is to facilitate a single crystal of a new composition to grow.

### CROSS REFERENCE TO RELATED APPLICATIONS

The present application claims priority to Korean Patent Application No. 10-2023-0179978, filed Dec. 12, 2023, the entire contents of which are incorporated herein for all purposes by this reference.

### BACKGROUND

### 1. Technical Field

The present disclosure relates to a method of forming a high-temperature superconducting single crystal and relates to a high-temperature superconducting single crystal formed thereby. More specifically, the present disclosure relates to a method capable of facilitating a high-temperature superconducting single crystal containing two or more types of rare-earth metals to grow using a multilayer seed and relates to a high-temperature superconducting single crystal formed thereby.

### 2. Description of the Related Art

In 1911, Heike Kamerlingh-Onnes of Leiden University in the Netherlands discovered a phenomenon in which electrical resistance suddenly disappeared at an absolute temperature of 4.2 K (268.8° C. below zero) while conducting an experiment to measure the electrical resistance of mercury. Starting with such discovery, low-temperature superconductors, such as niobium-titanium (NbTi) and tin-titanium (SnTi), began to be used in applications requiring high magnetic fields.

High-temperature superconductors were discovered by Johannes Bednorz and Karl Muller in Switzerland in 1987. Since then, research has been actively conducted on improving the critical temperature and critical current density of high-temperature superconductors.

Representative compositions of high-temperature superconductors include bismuth strontium calcium copper oxide (BSCCO) and rare-earth barium copper oxide (ReBCO). In this case, “Re” stands for rare-earth and refers to rare-earth elements.

Both compositions are present in a state where the oxygen content in copper (Cu) oxide is chemically unstable (Non-Stoichiometric compound). Thus, it is important to control the oxygen atmosphere when forming and using the same.

The foregoing is intended merely to aid in understanding the background of the present disclosure. The foregoing is not intended to mean that the present disclosure falls within the purview of the related art that is already known to those having ordinary skill in the art.

### SUMMARY

The present disclosure provides a method of forming a high-temperature superconducting single crystal capable of facilitating a high-temperature superconducting single crystal containing two or more types of rare-earth metals to grow using a multilayer seed. The present disclosure also provides a high-temperature superconducting single crystal formed by the method.

Technical problems to be solved by the present disclosure are not t limited to the technical problems mentioned above. It should be apparent that other technical problems not mentioned herein can be more clearly understood by those having ordinary skill in the art from the description of the present disclosure.

In order to achieve the above-mentioned objects, the present disclosure provides a method of forming a high-temperature superconducting single crystal. The method includes: placing a plurality of seeds that differ in lattice constant on a rare-earth barium copper oxide (ReBCO)-based precursor containing a rare-earth metal; melting a portion of the precursor by heating the precursor to a peritectic temperature thereof or higher; and growing a single crystal by cooling the precursor to a crystal growth temperature thereof to match a crystal orientation of the seeds.

According to one embodiment of the present disclosure, the following effects can be expected.

First, when using a superconducting material such as a wire, the critical current density of the wire applied to a driving motor can be increased. Thus, the magnetic field of a superconducting coil (racetrack) can be increased compared to the current level of wires, thereby maximizing power density.

Second, when used as a superconducting bulk magnet, an increase in critical t density leads to the maximization of magnetized magnetic fields, thereby maximizing the powder density of the motor.

Third, this can have direct advantages in manufacturing large-area single-crystalline superconductors and novel materials while not requiring new seeds to be developed.

### BRIEF DESCRIPTION OF THE DRAWINGS

FIG. 1 is a schematic diagram illustrating growth of a multilayer seed having a staircase-like structure using a method of forming a high-temperature superconducting single crystal of the present disclosure.

FIG. 2 is a flowchart illustrating one example of a method of forming a high-temperature superconducting single crystal of the present disclosure.

FIG. 3 is a graph showing a-axis and b-axis lattice constants of a (Gd₁₋ₓHoₓ)Ba₂Cu₃O_{7-δ} precursor (where Gd=gadolinium, Ho=holmium, Ba=barium, Cu=copper, 0=oxygen) (where 0.4<x<0.6, and 0<δ<7) and a NdBCO seed (where Nd=neodymium and BCO=barium copper oxide) measured using X-ray diffraction.

FIG. 4 is a diagram showing temperature changes during a heat treatment process of a method of forming a high-temperature superconducting single crystal of the present disclosure.

FIG. 5 is an image showing growth of a multilayer seed having a staircase-like structure using a method of forming a high-temperature superconducting single crystal of the present disclosure.

FIG. 6 is a graph showing magnetic susceptibility with varying Ho content of a single-crystalline high-temperature superconductor at a temperature of 10 K.

FIG. 7 is a graph showing critical current density with varying Ho content of a single-crystalline high-temperature superconductor at a temperature of 10 K through the extended Bean critical state model.

FIG. 8 is a graph showing critical current density with varying Ho content of polycrystalline and single-crystalline high-temperature superconductors at a temperature of 10 K.

### DETAILED DESCRIPTION

Hereinafter, embodiments disclosed herein are described in detail with reference to the attached drawings. The same reference numerals are used throughout the drawings to identify the same or like elements, and redundant descriptions thereof have been omitted.

The terms “module” and “unit” for the elements used in the following description are added or mixed considering only for the convenience of writing the specification. Such terms do not have meanings or functions that are distinguished from each other by themselves.

In the following description of the embodiments disclosed herein, it is to be noted that, when the functions of conventional elements and the detailed description of elements related with the present disclosure may have made the gist of the present disclosure unclear, a detailed description of those elements has been omitted. Additionally, the embodiments described herein, and the configurations illustrated in the drawings are merely examples and do not exhaustively present the technical spirit of the present disclosure. Furthermore, the present disclosure is intended to cover not only the embodiments but also various alternatives, modifications, equivalents, and other embodiments that may be included within the spirit and scope of the present disclosure.

Terms used herein, such as “first”, “second”, etc., may be used to describe various components, but the components are not to be construed as being limited by the terms. These terms are used only for the purpose of distinguishing a component from another component.

It should be understood that, when an element is referred to as being “coupled” or “connected” to another element, it can be directly coupled or connected to the other element, or intervening elements may be present therebetween. In contrast, it should be understood that, when an element is referred to as being “directly coupled” or “directly connected” to another element, there are no intervening elements present.

The singular expression includes the plural expression unless the context clearly indicates otherwise.

It should be further understood that the terms “comprises”, “includes”, or “has” and variations thereof used herein specify the presence of stated features, regions, integers, steps, operations, elements, and/or components. Such terms do not preclude the presence or addition of one or more other features, regions, integers, steps, operations, elements, components, and/or combinations thereof.

The present disclosure relates to a method of forming a high-temperature superconducting single crystal. The method is capable of facilitating a high-temperature superconducting single crystal containing rare-earth metals to grow using a multilayer seed for reducing a large difference in lattice constant between a precursor and the seed in top-seeded melt growth. The present disclosure also relates to a high-temperature superconducting single crystal formed by the method.

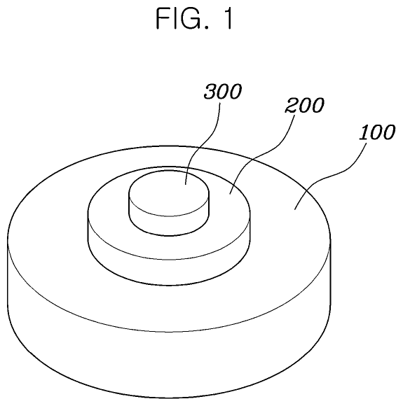

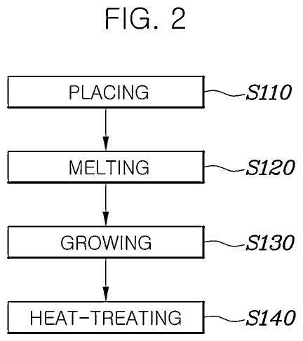

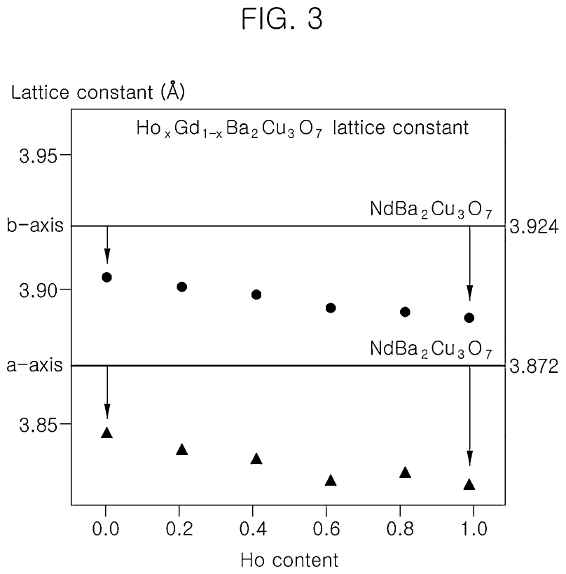

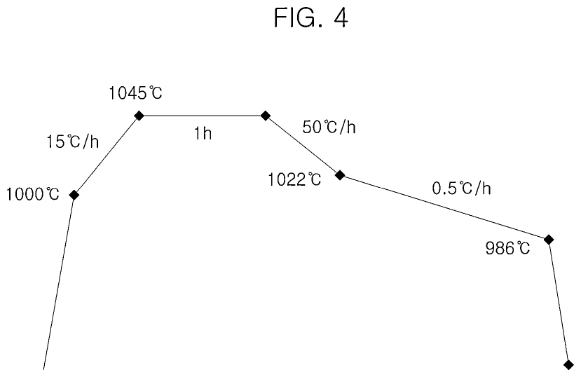

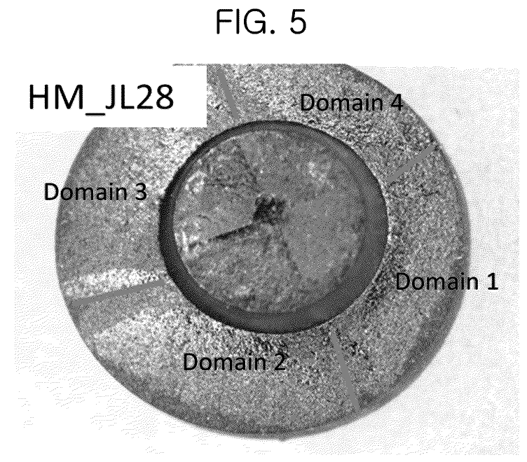

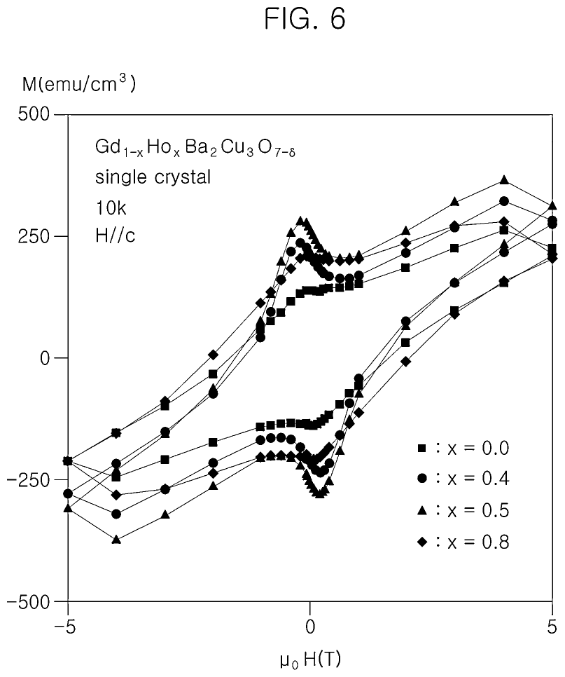

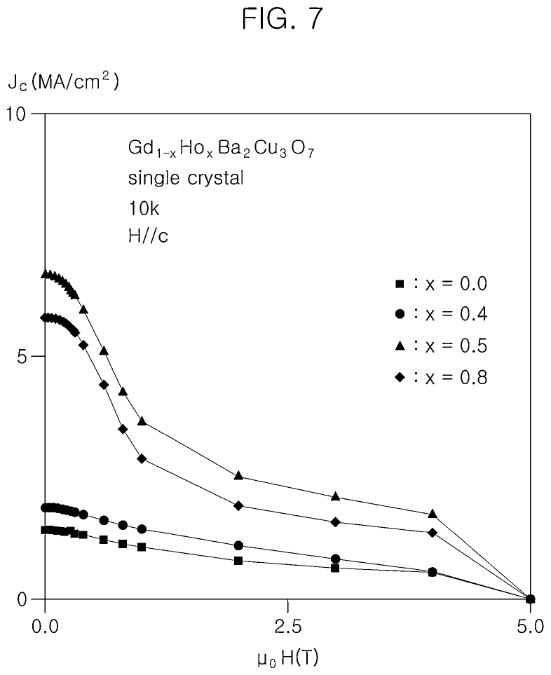

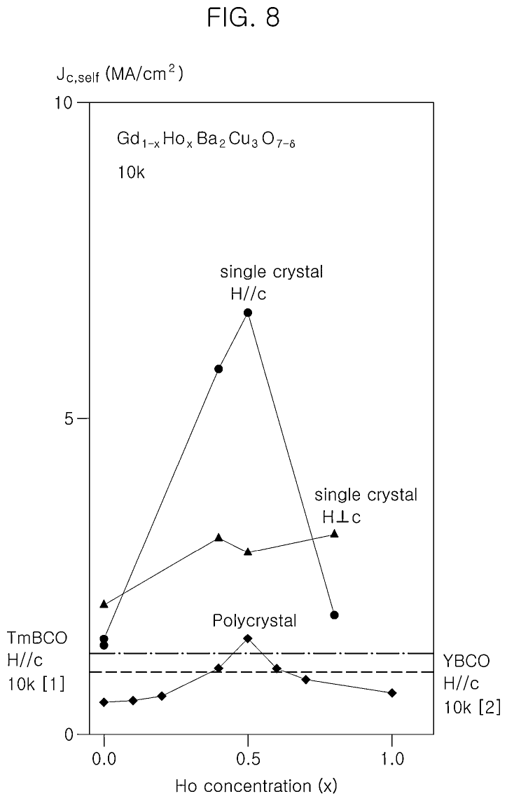

FIG. 1 is a schematic diagram illustrating growth of a multilayer seed having a staircase-like structure using a method of forming a high-temperature superconducting single crystal of the present disclosure. FIG. 2 is a flowchart illustrating one example of a method of forming a high-temperature superconducting single crystal of the present disclosure. FIG. 3 is a graph showing a-axis and b-axis lattice constants of a (Gd₁₋ₓHoₓ)Ba₂Cu₃O_{7-δ} precursor (where Gd=gadolinium, Ho=holmium, Ba=barium, Cu=copper, O=oxygen) (where 0.4<x<0.6, and 0<δ<7) and a NdBCO seed (where Nd=neodymium and BCO=barium copper oxide) measured using X-ray diffraction. FIG. 4 is a diagram showing temperature changes during a heat treatment process of a method of forming a high-temperature superconducting single crystal of the present disclosure. FIG. 5 is an image showing growth of a multilayer seed having a staircase-like structure using a method of forming a high-temperature superconducting single crystal of the present disclosure. FIG. 6 is a graph showing magnetic susceptibility with varying Ho content of a single-crystalline high-temperature superconductor at a temperature of 10 K. FIG. 7 is a graph showing critical current density with varying Ho content of a single-crystalline high-temperature superconductor at a temperature of 10 K through the extended Bean critical state model. FIG. 8 is a graph showing critical current density with varying Ho content of polycrystalline and single-crystalline high-temperature superconductors at a temperature of 10 K.

As illustrated in FIG. 1, a plurality of seeds that differ in lattice constant is placed on a rare-earth barium copper oxide (ReBCO)-based precursor containing rare-earth metals.

In this case, the precursor may be a ReBCO-based precursor containing rare-earth metals.

For example, the precursor may be a (Gd,Ho)BCO-based precursor containing Gd and Ho as rare-earth metals but is not limited thereto.

Additionally, the (Gd,Ho)BCO-based precursor may be (Gd₁₋ₓHoₓ)Ba₂Cu₃O_{7-δ} (where 0.4<x<0.6, and δ<7) improving superconductivity.

On the other hand, the precursor may be a ReBCO-based polycrystal.

The plurality of seeds may include buffer crystals and seed crystals.

In top-seeded melt growth, the buffer crystals may be placed between the precursor and the seed crystals to reduce differences in lattice constant and peritectic temperature between the seed crystals and the precursor.

A difference in lattice constant between the precursor and the buffer crystals may be smaller than the difference in lattice constant between the precursor and the seed crystals.

The difference in lattice constant between the precursor and the buffer crystals may be at a level of 0.8% or less based on the lattice constant of the precursor.

A difference in peritectic temperature between the precursor and the buffer crystals may be smaller than the difference in lattice constant between the precursor and the seed crystals.

The peritectic temperature of the seed crystals may be higher than that of the precursor.

The buffer crystals may be GdBa₂Cu₃O_{7-δ} (where δ<7).

Additionally, the seed crystals may be NdBa₂Cu₃O_{7-δ} (where δ<7).

ReBCO, used in high-temperature superconductors, exhibits a critical current that varies greatly depending on the texture thereof. Typically, a single crystal has a greater critical current value than a polycrystal, meaning that the single crystal has excellent high-temperature superconducting performance.

Single-crystalline superconductors are manufactured through top-seeded melt growth based on polycrystalline superconductors.

Top-seeded melt growth is a method of manufacturing a single-crystalline ReBCO high-temperature semiconductor from seeds by placing single-crystalline seeds on top of a precursor, which is a polycrystalline superconductor, having the same crystalline structure as and a lower melting point than the single-crystalline seeds, heating the resulting specimen to a peritectic temperature or higher, immediately cooling the specimen below the peritectic point, and gradually cooling the specimen.

In this case, the single-crystalline ReBCO high-temperature superconductor is subjected to oriented epitaxial growth.

Epitaxial growth refers to a phenomenon where an oriented crystalline film grows on a crystal substrate.

In the case of GdBCO or yttrium barium copper oxide (YBCO), high-quality single-crystalline superconductors may generally be manufactured using NdBCO or samarium barium copper oxide (SmBCO) seeds.

However, when the differences in lattice constant and peritectic temperature between the polycrystalline ReBCO-based precursor and the seed are at predetermined levels or higher, there is a problem in that a single-crystalline superconductor fails to be manufactured.

FIG. 3 is a graph showing a-axis and b-axis lattice constants of a (Gd₁₋ₓHoₓ)Ba₂Cu₃O_{7-δ} precursor (where 0.4<x<0.6, and 0<δ<7) and NdBCO seed crystals measured using X-ray diffraction. The results of FIG. 3 are analyzed in Tables 1 and 2.

TABLE 1

| | NdBCO | GdBCO | (Gd_{0.5}, Ho_{0.5}) BCO |
|---|---|---|---|
| a-axis lattice | 0.3872 nm | 0.3842 nm | 0.3832 nm |
| constant | | | |
| b-axis lattice | 0.3924 nm | 0.3898 nm | 0.3891 nm |
| constant | | | |

Table 1 shows the a-axis and b-axis lattice constants of the NdBCO seed crystals, the GdBCO buffer crystals, and the (Gd_{0.5},Ho_{0.5})BCO precursor.

TABLE 2

| | NdBCO_(Gd_{0.5}, | GdBCO_(Gd_{0.5}, | |
|---|---|---|---|
| | Ho_{0.5}) | Ho_{0.5}) | |
| | BCO | BCO | GdBCO_NdBCO |
| a-axis error | 1.03% | 0.26% | 0.77% |
| rate | | | |
| b-axis error | 0.84% | 0.17% | 0.66% |
| rate | | | |

Table 2 shows the a-axis and b-axis error rates between the (Gd_{0.5},Ho_{0.5})BCO precursor and the NdBCO seed crystals and the a-axis and b-axis error rates between the (Gd_{0.5},Ho_{0.5})BCO precursor and the GdBCO buffer crystals.

Referring to these results, the method of forming the high-temperature superconducting single crystal of the present disclosure is described.

The lattice constant of the (Gd₁₋ₓHoₓ)Ba₂Cu₃O_{7-δ} precursor (where 0.4<x<0.6, and 0<δ<7) tends to decrease in proportion to the Ho content added, as shown in FIG. 3. Accordingly, the difference in lattice constant between the NdBCO seed crystals is confirmed to increase.

In the case of top-seeded melt growth, when there is a sharp difference in lattice constant between the seed on the top and the precursor, epitaxial growth, in which an oriented crystalline film grows on a crystalline substrate, may fail to be facilitated. This makes it impossible to manufacture a high-quality single-crystalline superconductor.

When the difference in value of such lattice constants is at a level of 0.8% or more, epitaxial growth fails to be facilitated.

Therefore, in the case of typical top-seeded melt growth, the error rates of the a-axis and b-axis lattice constants between the (Gd_{0.5},Ho_{0.5})BCO precursor (where x=0.5) and the NdBCO seed crystals are 1.03% and 0.84%, respectively. This makes it impossible to facilitate epitaxial growth.

However, in the case of the method of forming the high-temperature superconducting single crystal of the present disclosure, the difference in lattice constant was reduced by placing the GdBCO buffer crystals between the (Gd_{0.5},Ho_{0.5})BCO precursor (where x=0.5) and the NdBCO seed crystals.

Specifically, the error rates of the a-axis and b-axis lattice constants between the (Gd_{0.5},Ho_{0.5})BCO precursor (where x=0.5) and the GdBCO buffer crystals are 0.26% and 0.17%, respectively.

Additionally, the error rates of the a-axis and b-axis lattice constants between the NdBCO seed crystals and the GdBCO buffer crystals are 0.77% and 0.66%, respectively.

As described above, both differences in lattice constants between the GdBCO buffer crystals and the precursor and between the GdBCO buffer crystals and the seed crystals are low at levels of 0.8% or less.

This means that the GdBCO buffer crystals effectively reduce the difference in lattice constant between the (Gd_{0.5},Ho_{0.5})BCO precursor and the NdBCO seed crystals. This makes epitaxial growth to be facilitated regardless of a large difference in lattice constant between the (Gd_{0.5},Ho_{0.5})BCO precursor and the NdBCO seed crystals when using the method of forming the high-temperature superconducting single crystal of the present disclosure.

FIG. 2 is a flowchart illustrating one example of the method of forming the high-temperature superconducting single crystal of the present disclosure. Referring to FIG. 2, the method of forming the high-temperature superconducting single crystal of the present disclosure is described.

The method of the present disclosure may include Step S110 of placing a plurality of seeds that differ in lattice constant on a ReBCO-based precursor containing rare-earth metals.

The ReBCO-based precursor may be a (Gd,Ho)BCO-based precursor containing Gd and Ho as rare-earth metals.

In this case, the (Gd,Ho)BCO-based precursor may be (Gd₁₋ₓHoₓ)Ba₂Cu₃O_{7-δ} (where 0.4<x<0.6, and 0<δ<7).

Additionally, the placing step may include a step of preparing a polycrystalline ReBCO-based precursor, which may be as follows. However, this is disclosed for illustrative purposes, and the present disclosure is not limited thereto.

### Method of Preparing Polycrystalline Precursor

First, 99.9% or more of gadolinium (III) oxide (Gd₂O₃), barium carbonate (BaCO₃), copper (II) oxide (CuO), and Ho powders are mixed according to chemical composition amounts.

The powders are stirred for 10 minutes using a mortar to be well mixed.

A molded body is produced by applying a pressure in a range of 5 to 20 megapascal (Mpa) in a jig to form the mixed powder into a green body.

Heat treatment is performed to manufacture a superconductor from the produced molded body.

In primary heat treatment, the temperature is heated at a rate of 120° C. per hour so that heat treatment is performed at 880° C. for 20 hours and then cooled at a rate of 120° C. per hour. This is to control the carbon (C) content present as an impurity in an oxide material.

In secondary heat treatment, the temperature is heated at a rate of 120° C. per hour so that heat treatment is performed at 900° C. for 20 hours and then cooled at a rate of 120° C. per hour. This is to obtain (Gd,Ho)BCO.

In tertiary heat treatment, the temperature is heated at a rate of 120° C. per hour so that heat treatment is performed at 925° C. for 15 hours and then cooled at a rate of 120° C. per hour. This is to increase the grain size of (Gd,Ho)BCO crystals and obtain stable crystallinity.

The plurality of seeds that differ in lattice constant may be stacked on the surface of the ReBCO-based precursor.

The plurality of seeds may include the buffer crystals in which the difference in lattice constant between the precursor is at a predetermined level or lower and the seed crystals in which the difference in lattice constant between the precursor is at a predetermined level or higher.

In this case, the difference in lattice constant between the precursor and the buffer crystals may be at a level of 0.8% or less.

Additionally, the buffer crystals, in which the difference in lattice constant between the precursor is at a predetermined level or lower, are placed close to the precursor, and the seed crystals, in which the difference in lattice constant between the precursor is at a predetermined level or higher, are placed apart from the precursor.

The seed crystals may be NdBa₂Cu₃O_{7-δ} (where 0<δ<7).

The buffer crystals may be GdBa₂Cu₃O_{7-δ} (where 0<δ<7).

The method of the present disclosure may include Step S120 of melting a portion of the precursor by heating the precursor to a peritectic temperature thereof or higher.

FIG. 4 is a diagram showing a temperature profile of (Ho_{0.4}Gd_{0.6})Ba₂Cu₃O_{7-δ}, which is one example of the method of forming the high-temperature superconducting single crystal of the present disclosure. Referring to FIG. 4, one example of the method of forming the high-temperature superconducting single crystal of the present disclosure is described.

Examples of top-seeded melt growth include cold seeding and hot seeding, where cold seeding is a method of placing seeds on a precursor before heating the precursor to a peritectic temperature thereof, and hot seeding is a method of placing seeds on a precursor after heating the precursor to a peritectic temperature thereof or higher. In the method of forming the high-temperature superconducting single crystal of the present disclosure, both cold seeding and hot seeding are applicable. Cold seeding is usable for the ease of process.

The melting step may include: a first heating process in which the precursor is heated to a first heating temperature; and a second heating process in which the precursor is heated to a second heating temperature higher than the first heating temperature.

In this case, the first heating temperature may be lower than the peritectic temperature of the precursor.

After heating the precursor to the first heating temperature, the temperature may be heated to the second heating temperature.

The second heating temperature may be higher than the peritectic temperature of the precursor and lower than the peritectic temperature of the seed crystals. Alternatively, the second heating temperature may also be around the peritectic temperature of the buffer crystals. This is to make the precursor semi-molten.

For example, the first heating temperature may be 1000° C., which is lower than the peritectic temperature of the (Ho_{0.4}Gd_{0.6})Ba₂Cu₃O_{7-δ} precursor at 1022° C. The second heating temperature may be 1045° C., which is higher than the peritectic temperature of the (Ho_{0.4}Gd_{0.6})Ba₂Cu₃O_{7-δ} precursor at 1022° C.

The method of the present disclosure may include Step S130 of growing a single crystal by cooling the precursor to a crystal growth temperature of the precursor to match a crystal orientation of the seeds.

FIG. 4 is a diagram showing the temperature profile in the method of forming the high-temperature superconducting single crystal of the present disclosure. Referring to FIG. 4, one example of the method of forming the high-temperature superconducting single crystal of the present disclosure is described.

The growing step may include: a first growth process in which the seeds are cooled to a first growth temperature; a second growth process in which the seeds are cooled to a second growth temperature lower than the first growth temperature to grow the high-temperature superconducting single crystal; and a third growth process in which the grown single crystal is cooled to room temperature.

The precursor that has become semi-molten through the heating processes in which the temperature is heated to the second heating temperature higher than the peritectic temperature of the precursor is subjected to the first growth process in which the temperature is cooled to the first growth temperature, which is the peritectic temperature of the precursor.

Next, the seeds are subjected to the second growth process in which the temperature is cooled from the first growth temperature to the second growth temperature.

In this case, the first growth temperature may be the peritectic temperature of the precursor.

Additionally, the second growth temperature may be the crystal growth temperature, which is lower than the peritectic temperature of the precursor.

Additionally, the cooling rate of the second growth process may be lower than the cooling rate of the first growth process. This is to achieve process efficiency through rapid cooling from the second heating temperature to the first growth temperature and to achieve stable growth of the ReBCO high-temperature semiconducting single crystal by a gradual temperature change from the peritectic temperature of the precursor to the crystal growth temperature through gradual cooling from the first growth temperature to the second growth temperature.

Next, the grown single crystal is subjected to the third growth process in which the temperature is cooled to room temperature.

As described above, after making the precursor semi-molten, the epitaxial growth of the single crystal is effectively enabled through a slow cooling process from the peritectic temperature, thereby effectively providing the ReBCO high-temperature superconducting single crystal.

For example, the first growth temperature may be around the peritectic temperature of the (Ho_{0.4}Gd_{0.6})Ba₂Cu₃O_{7-δ} precursor at 1022° C., and the second growth temperature may be around the crystal growth temperature at 986° C., which is lower than peritectic temperature of the (Ho_{0.4}Gd_{0.6})Ba₂Cu₃O_{7-δ} precursor at 1022° C. Additionally, the cooling rate of the first growth process, in which the temperature is cooled from the first heating temperature to the first growth temperature, is 50° C./h (degree Celsius per hour). Furthermore, the cooling rate of the second growth process, in which the temperature is cooled from the first growth temperature to the second growth temperature, is 0.50° C./h, which is lower than the cooling rate of the first growth process.

Next, the method of the present disclosure may include step S140 of heat-treating the ReBCO high-temperature superconducting single crystal.

The grown single-crystalline superconductor requires sufficient heat treatment to develop effective superconductivity.

In this case, the heat-treating step may be performed in an oxygen atmosphere.

The heat-treating step may be performed at a temperature in a range of 400° C. to 600° C. and is performed in one example at 500° C.

The heat-treating step may be performed for 150 to 170 hours and is performed in one example for 160 hours.

The method of forming the high-temperature superconducting single crystal described above enables the ReBCO high-temperature superconducting single crystal with excellent performance to be provided.

Hereinafter, experimental data based on examples is described to explain the effects of a method of forming a high-temperature superconducting single crystal of the present disclosure and a high-temperature superconducting single crystal formed thereby.

### Example

As illustrated in FIG. 1, buffer crystals 200 were placed on a precursor 100, and seed crystals 300 were placed on the buffer crystals. Next, a Ho_{0.4}Gd_{0.6}Ba₂Cu₃O_{7-δ} high-temperature superconducting single crystal was formed according to a method of forming a high-temperature superconducting single crystal of the present disclosure (peritectic temperature: 1022° C.).

In this case, the precursor 100 includes 70 wt % of polycrystalline Ho_{0.823}Gd_{0.177}Ba₂Cu₃O_{7-δ} and 30 wt % of polycrystalline Gd₂BaCuO₅.

The buffer crystals 200 include 70 wt % of GdBa₂Cu₃O₇ and 30 wt % of GdBaCuO₅.

The seed crystals 300 include single-crystalline NdBa₂Cu₃O₇.

As a result, a high-quality sample of a (Gd_{0.6},Ho_{0.4})BCO high-temperature superconducting single crystal was prepared, as shown in FIG. 5.

The physical properties of the grown single-crystalline (Gd,Ho)BCO superconductor were evaluated through the Magnetic Property Measurement System (MPMS), and the critical current density was evaluated through the extended Bean critical state model.

FIG. 6 is a graph showing magnetic susceptibility with varying Ho content of the single-crystalline high-temperature superconductor at a temperature of 10 K. FIG. 7 is a graph showing critical current density with varying Ho content of a single-crystalline high-temperature superconductor at a temperature of 10 K through the extended Bean critical state model. The y-axis in FIG. 7 represents critical current density.

This confirms that the Ho_{0.823}Gd_{0.177}Ba₂Cu₃O_{7-δ} single-crystalline high-temperature superconductor, formed by the method of forming the high-temperature superconducting single crystal of the present disclosure, has a critical current density superior to that of an existing GdBa₂Cu₃O_{7-δ} single-crystalline high-temperature superconductor.

FIG. 8 is a graph showing critical current density with varying Ho content of polycrystalline and single-crystalline high-temperature superconductors at a temperature of 10 K. The y-axis in FIG. 8 represents critical current density.

This confirms that the HOₓGd₁₋ₓBa₂Cu₃O_{7-δ} single-crystalline high-temperature superconductor, formed by the method of forming the high-temperature superconducting single crystal of the present disclosure, has a critical current density superior to that of an existing HoₓGd₁₋ₓBa₂Cu₃O_{7-δ} polycrystalline high-temperature superconductor.

Thus, the method of forming the high-temperature superconducting single crystal of the present disclosure enables a high-temperature superconducting single crystal with excellent performance to be provided. This is possible because the buffer crystals reduce the difference in lattice constant between the seed crystals and the precursor.

Although the present disclosure is provided above in relation to specific embodiments shown in the drawings, it should be apparent to those having ordinary skill in the art that the present disclosure may be changed and modified in various ways without departing from the scope of the present disclosure, which is described in the following claims.

1. A method of forming a high-temperature superconducting single crystal, the method comprising:
placing a plurality of seeds that differ in lattice constant on a rare earth metal barium copper oxide (ReBCO)-based precursor containing a rare-earth metal;
melting a portion of the ReBCO-based precursor by heating the ReBCO-based precursor to a peritectic temperature thereof or higher; and
growing a single crystal by cooling the ReBCO-based precursor to a crystal growth temperature thereof to match a crystal orientation of the plurality of seeds.

2. The method of claim 1, wherein the ReBCO-based precursor is a gadolinium holmium barium copper oxide ((Gd,Ho)BCO)-based precursor comprising Gd and Ho as the rare-earth metals.

3. The method of claim 2, wherein the (Gd,Ho)BCO-based precursor is (Gd₁₋ₓHoₓ)Ba₂Cu₃O_{7-δ} (where 0.4<x<0.6, and δ<7) (where Ba=barium, Cu=copper, 0=oxygen).

4. The method of claim 1, wherein the ReBCO-based precursor is prepared by:
mixing gadolinium (III) oxide (Gd₂O₃), barium carbonate (BaCO₃), copper (II) oxide (CuO), and Ho-containing powders according to chemical composition amounts to prepare a mixed powder; and
shaping the mixed powder by applying a pressure to prepare the precursor.

5. The method of claim 1, wherein:
the plurality of seeds comprises seed crystals and buffer crystals; and
a difference in lattice constant between the ReBCO-based precursor and the buffer crystals is smaller than a difference in lattice constant between the precursor and the seed crystals.

6. The method of claim 5, wherein a difference in peritoneal temperature between the ReBCO-based precursor and the buffer crystals is smaller than a difference in peritectic temperature between the ReBCO-based precursor and the seed crystals.

7. The method of claim 5, wherein the difference in lattice constant between the ReBCO-based precursor and the buffer crystals is at a level of 0.8% or less.

8. The method of claim 5, wherein the seed crystals are NdBa₂Cu₃O_{7-δ} (where δ<7).

9. The method of claim 5, wherein the buffer crystals are GdBa₂Cu₃O_{7-δ} (where δ<7).

10. The method of claim 5, wherein in placing the plurality of seeds, the buffer crystals are placed closer to the ReBCO-based precursor and the seed crystals are placed further from the ReBCO-based precursor.

11. The method of claim 1, wherein melting the portion of the ReBCO-based precursor comprises:
a first heating process in which the ReBCO-based precursor is heated to a first heating temperature; and
a second heating process in which the ReBCO-based precursor is heated to a second heating temperature higher than the first heating temperature.

12. The method of claim 11, wherein:
the first heating temperature is lower than the peritectic temperature of the ReBCO-based precursor; and
the second heating temperature is higher than the peritectic temperature of the ReBCO-based precursor and lower than a peritectic temperature of the seed crystals.

13. The method of claim 1, wherein the growing comprises:
a first growth process in which the plurality of seeds is cooled to a first growth temperature;
a second growth process in which the plurality of seeds is cooled to a second growth temperature lower than the first growth temperature to grow the single crystal; and
a third growth process in which the grown single crystal is cooled to room temperature.

14. The method of claim 13, wherein:
the first growth temperature of the first growth process is the peritectic temperature of the ReBCO-based precursor; and
the second growth temperature of the second growth process is the crystal growth temperature, which is lower than the peritectic temperature of the ReBCO-based precursor.

15. The method of claim 13, wherein a cooling rate of the first growth process is higher than a cooling rate of the second growth process.

16. A high-temperature superconducting single crystal formed according to the method of claim 1.

17. The high-temperature superconducting single crystal of claim 16, wherein the high-temperature superconducting single crystal is (Gd₁₋ₓHoₓ)Ba₂Cu₃O_{7-δ} (where 0.4<x<0.6, and δ<7).
